(19) United States
(12) Patent Application Publication
(10) Pub. No.: US 2016/0341998 A1
(43) Pub. Date: Nov. 24, 2016

(54) Display Substrate, Method for Manufacturing Display Substrate and Display Device

(71) Applicants: BOE TECHNOLOGY GROUP CO., LTD., Beijing (CN); Chengdu BOE Optoelectronics Technology Co., Ltd., Chengdu (CN)

(72) Inventors: Xiongcan ZUO, Beijing (CN); Junrui ZHANG, Beijing (CN)

(21) Appl. No.: 15/136,453

(22) Filed: Apr. 22, 2016

(30) Foreign Application Priority Data
May 21, 2015 (CN) 201510263087.6

(51) Int. Cl. G02F 1/139; G02F 1/1337; G02F 1/1368; H01L 27/12; G02F 1/1335

(52) U.S. Cl. CPC G02F 1/1396; H01L 27/12; G02F 1/133514; G02F 1/1368; G02F 1/1337; G02F 1/133528

(57) ABSTRACT

The present invention relates to the technical field of display, and particularly, to a display substrate, a method for manufacturing a display substrate and a display device. The display substrate includes a CF substrate and a TFT substrate disposed opposite to each other, and a liquid crystal layer disposed between the CF substrate and the TFT substrate, a first orientation layer disposed on the side of the CF substrate towards the liquid crystal layer, a second orientation layer disposed on the side of the TFT substrate towards the liquid crystal layer; a viewing angle compensation layer is disposed between the CF substrate and the first orientation layer, and between the TFT substrate and the second orientation layer. The display substrate is good at anchoring the orientation of liquid crystal, so that it can obtain better display quality of wide viewing angle.

### TECHNICAL FIELD

The present invention relates to the technical field of display, and particularly, to a display substrate, a method for manufacturing a display substrate and a display device.

BACKGROUND ART

TN type (ECB type or OCB type and so on) liquid crystal display devices have a narrow viewing angle (about 40°) due to arrangement of liquid crystal thereof. In order to compensate the viewing angle, a layer of discotic liquid crystal molecule (referred to as DLC) is coat on triacetate cellulose ester (hereafter referred to as TAC) base film in a polarizer to make the orientation of DLC antiparallel to the orientation of liquid crystal (referred to as LC) molecule in a liquid crystal cell, and the viewing angle can thus be widened from about 40° to about 80°. This approach is provided by Japan FujiFilm Corporation, and so far, is the most popular and the only approach.

The specific structure of the TN type liquid crystal display device with a wide viewing angle described above is shown in FIG. 1. In the display device, a liquid crystal cell is mainly constituted by a color filter (hereafter referred to as CF) substrate 21 and a thin film transistor (hereafter referred to as TFT) substrate 22, wherein an orientation layer 3 is coated on the CF substrate 21 and the TFT substrate 22 respectively, and the initial orientation direction of the orientation layer 3 is shown as the dashed arrow in FIG. 1, which leads the orientation direction of TN type liquid crystal molecule 4 to form a gradient angle arrangement as shown in FIG. 1. Meanwhile, a polarizer 1 on the CF substrate 21 is mainly composed of a surface treatment layer 11, a upper TAC layer 12, a PVA layer 13, a lower TAC layer 14 and a DLC layer 15 coated on the lower TAC layer 14, and a PSA layer 16, wherein the DLC layer 15 has an orientation direction 151 having a gradient angle arrangement complementary to that of liquid crystal molecule 4, the PSA layer 16 plays a role of adhering the polarizer 1 onto the CF substrate 21. Similarly, a polarizer 5 on the TFT substrate 22 is mainly composed of a PSA layer 56, a upper TAC layer 54 and a DLC layer 55 coated on the upper TAC layer 54, a PVA layer 53 and a lower TAC layer 52, wherein the DLC layer 55 has an orientation direction 551 complementary to the liquid crystal molecule 4.

When the liquid crystal display device with above structure is in a reliability environment such as high temperature and high humidity or hot and cold impact and so on, the PSA layers 16, 56 and TAC layers 12, 14, 52, 54 in the polarizers 1, 5 are easy to shrink (as shown in FIG. 2, pressure sensitive adhesive (hereafter referred to as PSA) and DLC-TAC shrink), resulting in the stress applied to the DLC layers 15, 55 on the TAC base film changes, which causes disorder of the long axis direction of DLC, i.e. non-perpendicular to the long axis direction of LC. This further causes disorder of the orientation directions 151, 551 of the liquid crystal molecule in these layers too, which is shown as disordered orientation directions 1511, 5511 in FIG. 3. In this case, the two DLC layers have so large overall birefringence that they could not compensate the viewing angle, so that a poor display performance of sandglass unevenness (sandglass mura) occurs. This phenomenon most obviously occurs on large-sized products. And so far no polarizer manufacturer has found an effective method for improving.

### SUMMARY OF INVENTION

In order to solve the above mentioned problems in the prior art, the present invention provides a display substrate, a method for manufacturing a display substrate and a display device, wherein the display substrate is good at anchoring the orientation of liquid crystal molecular and has a stable performance, so that it can obtain a better display quality of wide viewing angle.

The technical solution adopted to solve the technical problem of the present invention is: a display substrate, including a CF substrate and a TFT substrate disposed opposite to each other, and a liquid crystal layer disposed between said OF substrate and said TFT substrate, a first orientation layer disposed on the side of said CF substrate towards said liquid crystal layer, a second orientation layer disposed on the side of said TFT substrate towards said liquid crystal layer, characterized in that, a viewing angle compensation layer is disposed respectively between said CF substrate and said first orientation layer, and between said TFT substrate and said second orientation layer.

Preferably, the viewing angle compensation layer is formed by a Reactive Mesogens material.

Preferably, the viewing angle compensation layer has a thickness of 1 μm to 3 μm.

Preferably, a polarizer is disposed on the side of said CF substrate away from said liquid crystal layer, and on the side of said TFT substrate away from said liquid crystal layer.

A method of manufacturing a display substrate, said display substrate includes a CF substrate, a TFT substrate and a liquid crystal layer disposed between said CF substrate and said TFT substrate, a first orientation layer disposed on the side of said CF substrate towards said liquid crystal layer, a second orientation layer disposed on the side of said TFT substrate towards said liquid crystal layer, characterized in that, said manufacturing method includes a step of forming a viewing angle compensation layer between said CF substrate and said first orientation layer, and between said TFT substrate and said second orientation layer.

Preferably, the viewing angle compensation layer is formed by a Reactive Mesogens material.

Preferably, the formation of said viewing angle compensation layer includes: forming the Reactive Mesogens material respectively on one side of the CF substrate and one side of the TFT substrate by a coating method;

heating and pre-curing the Reactive Mesogens material;

orienting the Reactive Mesogens material by a UV light alignment process.

Preferably, heating and pre-curing the Reactive Mesogens material is carried out in a thermostatic heating mode, and the heating temperature ranges from 115° C. to 125° C.; the wavelength of UV light ranges from 320 nm to 420 nm.

A display device, including the display substrate described above.

Preferably; the display device includes a TN type display device, an ECB type display device and an OCB type display device.

The invention has advantageous effects as follows. The viewing angle of display is compensated by having a RM material in the display substrate thanks to the material's characteristic of fixing and polymerizing liquid crystal phase. Compared to current technical solution of disposing a DLC membrane in a polarizer base material outside the liquid crystal cell; the display substrate according to the present invention can avoid the poor display performance of sandglass unevenness due to the arrangement disorder of DLC layer liquid crystal molecule in the polarizer base material under high temperature and high humidity condition or hot and cold impact condition. Thereby image quality of the liquid crystal display device is enhanced to a certain degree in a high reliability environment.

Accordingly, a display device using said display substrate has a superior display quantity of wide viewing angle, and offers a better experience of viewing angle.

### DESCRIPTION OF THE DRAWINGS

FIG. 1 is a schematic view of the structure of a display substrate in the prior art;

FIG. 2 is a schematic view of the structure of the polarizer in the display substrate of FIG. 1 under hot and cold impact condition;

FIG. 3 is a schematic view of the orientation of the display substrate in FIG. 1 under the hot and cold impact condition in FIG. 2;

FIG. 4 is a schematic view of the structure of the display substrate in Example

FIGS. 5A and 5B are molecular formulas of RM material;

FIG. 6 is a schematic view of forming a viewing angle compensation layer by polymerization of RM material;

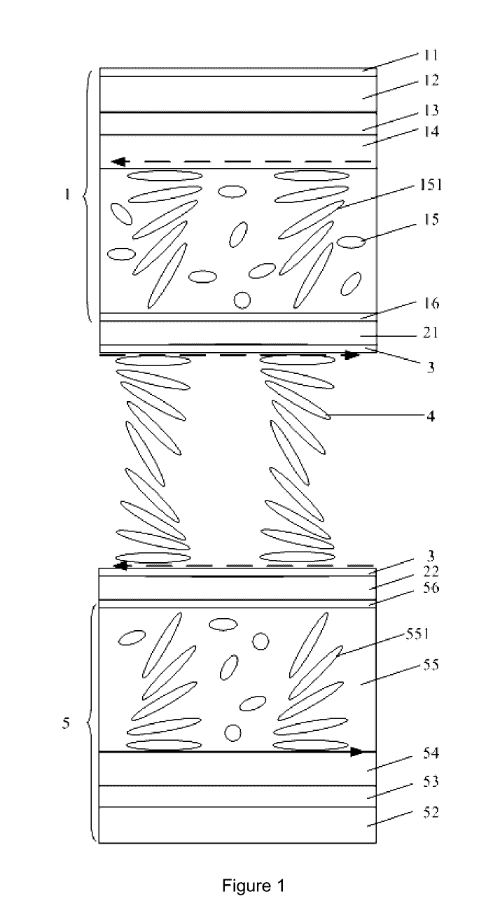

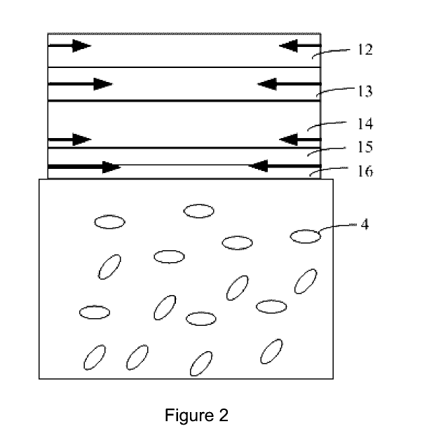

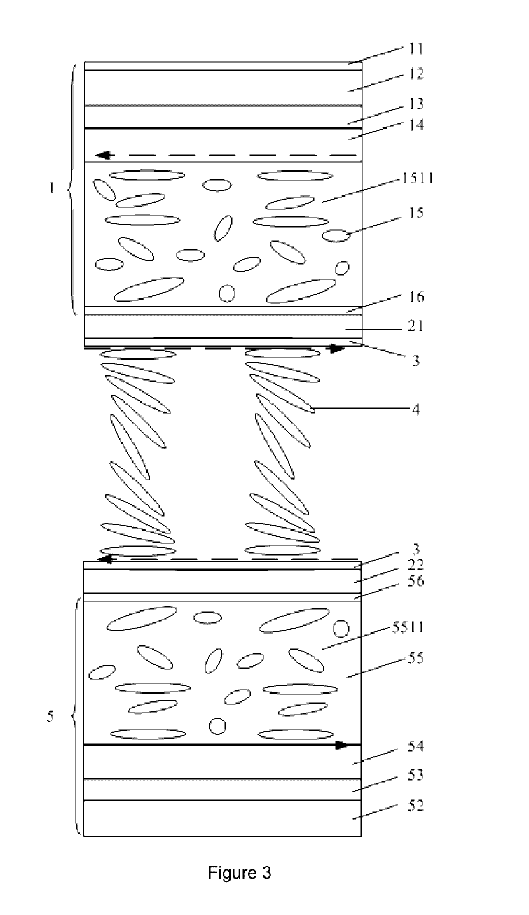

wherein:

1, 5—polarizer;

11—surface treatment layer;

12, 54—upper TAC layer; 13, 53—PVA layer; 14, 52—lower TAC layer;

15, 55—DLC layer;

151, 551, 1511, 5511—orientation direction;

16, 56—PSA layer;

21—CF substrate; 22—TFT substrate;

3—orientation layer; 3a—first orientation layer; 3b—second orientation layer;

4—liquid crystal molecule;

6,7—viewing angle compensation layer;

61,71—orientation direction;

8,9—ordinary polarizer.

### DESCRIPTION OF EMBODIMENTS

Hereafter, the display substrate and the method for manufacturing a display substrate and the display device according to the present invention will be further described in details with reference to the accompanying figures and specific embodiments, so that a person skilled in the art can get a better understanding of the technical solutions provided by the present invention.

### EXAMPLE 1

The Example provides a display substrate. The display substrate is good at anchoring the orientation of liquid crystal, so that it can obtain better display quality.

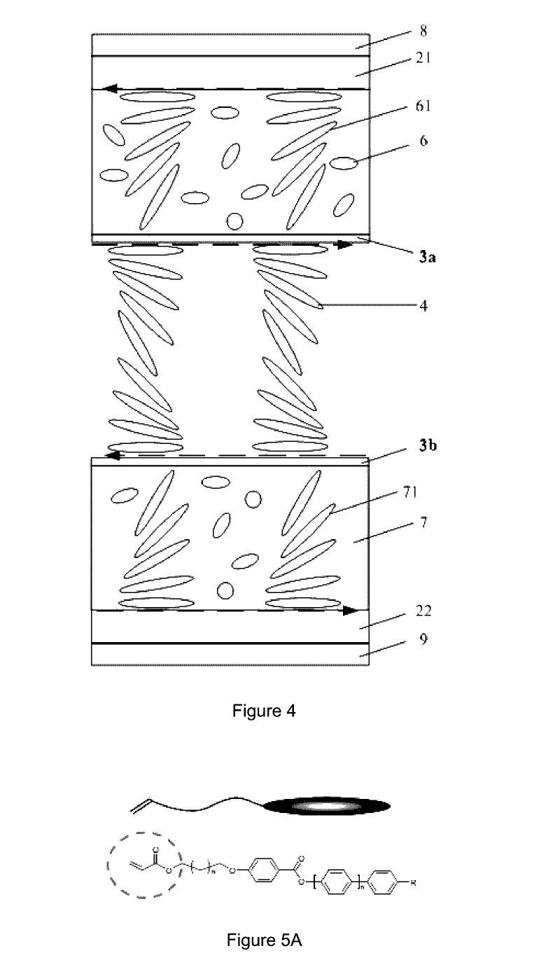

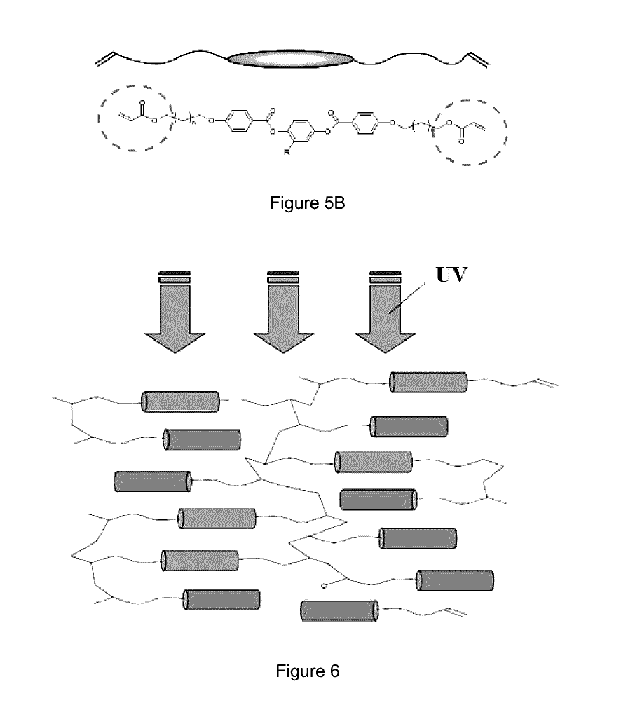

As shown in FIG. 4, the display substrate includes a CF substrate 21 and a TFT substrate 22 disposed opposite to each other, and a liquid crystal layer disposed between the CF substrate 21 and the TFT substrate 22; an orientation layer 3a disposed on the side of the CF substrate 21 towards the liquid crystal layer, an orientation layer 3b disposed on the side of the TFT substrate 22 towards the liquid crystal layer; a viewing angle compensation layer 6 is disposed between the CF substrate and the orientation layer 3a, a viewing angle compensation layer 7 is disposed between the TFT substrate and the orientation layer 3b.

Wherein, the viewing angle compensation layers 6 and 7 are formed by RM material. Currently, the RM material is developed by Merck Corporation mainly. A typical RM material is a reactive azobenzene liquid crystal material characterizing in having permanently fixed polymerized liquid crystal phase. Among them, a monoacrylate RM material has a molecular formula as shown in FIG. 5A, and a diacrylate RM material has a molecular formula as shown in FIG. 5B. As required, it is allowed to add additional active groups for polymerizing to achieve a core having similar properties to electro-optic liquid crystal materials. For example, films having appropriate optical performance and durability can be obtained depending on different active groups and desired coating method.

In the Example, by coating the RM materials on TFT substrate 22 and CF substrate 21, heating and pre-curing the RM materials, then orientating the RM materials by curing liquid crystal with UV light to, the long axis direction of the RM material liquid crystal molecule can be made approximately perpendicular to the long axis direction of LC, and the overall birefringence of them reaches the minimum, thus viewing angle is compensated. And further, extending orientation of the liquid crystal in the liquid crystal cell formed by the CF substrate 21 and the TFT substrate 22 is realized.

Preferably, the viewing angle compensation layer has a thickness of 1 μm to 3 μm, more preferably 2μm, which can obtain a better viewing angle compensation effect.

In order to control the backlight light, a polarizer is disposed on the side of the CF substrate 21 away from said liquid crystal layer, and on the side of the TFT substrate 22 away from said liquid crystal layer. Ordinary polarizers 8, 9 are just fine as the polarizer, there is no need to use the polarizer having a complicated structure and including a DLC liquid crystal molecule layer mentioned in background art.

As shown in FIG. 4, the invention is described in detail by taking a TN type liquid crystal display substrate achieving wide viewing angle for example. In FIG. 4, in the display substrate, the liquid crystal cell is mainly composed of the CF substrate 21 and the TFT substrate 22. A layer of RM material is coated on the inside of the CF substrate 21; a viewing angle compensation layer 6 is formed by thermostatic heating and pre-curing the RM material, and orienting the RM material by a UV light alignment process. The orientation direction of the viewing angle compensation layer 6 is the orientation direction 61 with gradient angle arrangement as shown in upper portion of FIG. 4. Then, a first orientation layer 3a is coated on the viewing angle compensation layer 6. The initial orientation direction of the first orientation layer 3a is shown as the dashed arrow in FIG. 4, and the TN type liquid crystal molecule 4 forms an orientation direction connecting with the angle gradient trend of the viewing angle compensation layer 6.

Similarly, a layer of RM material is coated on the inside of the TFT substrate 22 to form a viewing angle compensation layer 7 whose orientation direction is the orientation direction 71 with gradient angle arrangement as shown in lower portion of FIG. 4, then a second orientation layer 3b is coated on the viewing angle compensation layer 7, and the TN type liquid crystal molecule 4 forms an orientation direction connecting with the angle gradient trend of the viewing angle compensation layer 7. Lastly, an ordinary polarizer 8 is adhered to the outer side of the CF substrate 21, and an ordinary polarizer 9 is adhered to the outer side of the TFT substrate 22.

In the display substrate of the Example, since the viewing angle compensation layers 6, 7 are formed on the CF substrate 21 and the TFT substrate 22 respectively, compared to ordinary polarize membrane, the shrinking of the display substrate under high temperature and high humidity condition or hot and cold impact condition is very little, therefore the original orientation directions 61, 71 of the RM material liquid crystal molecules which play a role of viewing angle compensation are difficult to disorder, and are able to obtain a stable orientation effect. Thereby, the poor display performance of sandglass unevenness can be avoided effectively, and the image quality of the TN type display substrate in a high reliability condition can be improved while the viewing angle is compensated.

The present invention is described above by using the TN type liquid crystal display substrate as an example, however, it should be understood that, the display substrate is applicable to not only the TN type display substrate, but also other various liquid crystal display substrates that need viewing angle compensation. As for ECB type display substrates or ( )B type display substrates, it can also optically compensate liquid crystal molecules in the liquid crystal cell, and broaden viewing angle. Since the mechanism of broadening viewing angle thereof is the same as the TN type display substrate, so not mentioned here.

Accordingly, the Example further provides a method of manufacturing a display substrate. A display substrate with better orientation stability can be obtained by this simple and practical manufacturing method.

The display substrate in the method of manufacturing the same includes a CF substrate, a TFT substrate and a liquid crystal layer disposed between said CF substrate and said TFT substrate, a first orientation layer disposed on the side of said CF substrate towards said liquid crystal layer, a second orientation layer disposed on the side of said TFT substrate towards said liquid crystal layer; the manufacturing method includes a step of forming a viewing angle compensation layer between the CF substrate and the first orientation layer, and between the TFT substrate and the second orientation layer.

In the manufacturing method, specifically, the formation o he viewing angle compensation layer includes:

forming the Reactive Mesogens material on one side of the CF substrate and one side of the TFT substrate by coating, specifically, on the side which will face the liquid crystal layer after disposing the CF substrate and the TFT substrate opposite to each other;

heating and pre-curing the Reactive Mesogens material;

orienting the Reactive Mesogens material by a UV light alignment process to form the viewing angle compensation layer.

Since the technology of forming the viewing angle compensation layer through the manner described above is mature, the quality of display substrate can be ensured.

Wherein, heating and pre-curing the Reactive Mesogens material is carried out in a thermostatic heating mode, and the heating temperature preferably ranges from 115° C. to 125° C.; the wavelength of UV light ranges from 320 nm to 420 nm. As shown in FIG. 6, the UV light alignment process is adopted to polymerize the RM material so as to orientate the RM material liquid crystal molecule, thereby a viewing angle compensation layer with a fixed phase difference of liquid crystal molecule can be formed.

The display substrate in the Example adopts a viewing angle compensation layer formed by the RM material. Thanks to the material's characteristic of fixing and polymerizing liquid crystal phase, a viewing angle of greater than 80° can be obtained, thereby achieves the purpose of broadening viewing angle, and the substrate has a stable performance under high temperature and high humidity condition or hot and cold impact condition, and a better display quality.

### EXAMPLE 2

The Example provides a display device, including the display substrate in Example 1.

The display device may be any products or members with display function, for example, liquid crystal panel, electronic paper, mobile phones, tablet computers, televisions, display, notebook computers, digital frames, navigation and so on.

In the display device, the viewing angle of display is compensated by having a RM material in the display substrate thanks to the material's characteristic of fixing and polymerizing liquid crystal phase. Compared to current technical solution of disposing a DLC membrane in a polarizer base material outside the liquid crystal cell, the display substrate according to the present invention can avoid the poor display performance of sandglass unevenness due to the arrangement disorder of DLC layer liquid crystal molecule in the polarizer base material under high temperature and high humidity condition or hot and cold impact condition. Thereby image quality of the liquid crystal display device is enhanced to a certain degree in a high reliability environment.

Accordingly, said display device has a superior display quality of wide viewing angle, and offers a better experience of viewing angle.

It should be understood that the above embodiments of the invention have been described only for illustrating the principle of the present invention, but not intended to limit the present invention. The person skilled in the art can make various modifications and variations of the invention without departing from the spirit and scope of the invention, thus the modifications and variations of the invention are also included within the scope of the present invention.

1. A display substrate, including a CF substrate and a TFT substrate disposed opposite to each other, and a liquid crystal layer disposed between said CF substrate and said TFT substrate, a first orientation layer disposed on the side of said CF substrate towards said liquid crystal layer, a second orientation layer disposed on the side of said TFT substrate towards said liquid crystal layer, characterized in that, a viewing angle compensation layer is disposed between said CF substrate and said first orientation layer, and between said TFT substrate and said second orientation layer.

2. The display substrate according to claim 1, characterized in that, said viewing angle compensation layer is formed by a Reactive Mesogens material.

3. The display substrate according to claim 1, characterized in that, said viewing angle compensation layer has a thickness of 1 μm to 3 μm.

4. The display substrate according to claim 1, characterized in that, a polarizer is disposed on the side of said CF substrate away from said liquid crystal layer, and on the side of said TFT substrate away from said liquid crystal layer.

5. The display substrate according to claim 2, characterized in that, a polarizer is disposed on the side of said CF substrate away from said liquid crystal layer, and on the side of said TFT substrate away from said liquid crystal layer.

6. The display substrate according to claim 3, characterized in that, a polarizer is disposed on the side of said CF substrate away from said liquid crystal layer, and on the side of said TFT substrate away from said liquid crystal layer.

7. A method of manufacturing a display substrate including a CF substrate, a TFT substrate and a liquid crystal layer disposed between said CF substrate and said TFT substrate, a first orientation layer disposed on the side of said CF substrate towards said liquid crystal layer, a second orientation layer disposed on the side of said TFT substrate towards said liquid crystal layer, characterized in that, said manufacturing method includes a step of forming a viewing angle compensation layer between said CF substrate and said first orientation layer, and between said TFT substrate and said second orientation layer.

8. The method of manufacturing a display substrate according to claim 7, characterized in that, said viewing angle compensation layer is formed by a Reactive Mesogens material.

9. The method of manufacturing a display substrate according to claim 7, characterized in that, the formation of said viewing angle compensation layer includes:
forming the Reactive Mesogens material respectively on one side of the CF substrate and one side of the TFT substrate by a coating method;
heating and pre-curing the Reactive Mesogens material;
orienting the Reactive Mesogens material by a UV light alignment process.

10. The method of manufacturing a display substrate according to claim 8, characterized in that, heating and pre-curing the Reactive Mesogens material is carried out in a thermostatic heating mode, and the heating temperature ranges from 115° C. to 125° C.; the wavelength of UV light ranges from 320 nm to 420 nm.

11. A display device, characterized in that, it includes the display substrate according to claim 1.

12. A display device, characterized in that, it includes the display substrate according to claim 2.

13. A display device, characterized in that, it includes the display substrate according to claim 3.

14. A display device, characterized in that, it includes the display substrate according to claim 4.

15. A display device, characterized in that, it includes the display substrate according to claim 5,

16. A display device, characterized in that, it includes the display substrate according to claim 6.

17. A display device, characterized in that, it includes the display substrate according to claim 7.

18. The display device according to claim 11, characterized in that, said display device includes a TN type display device, an ECB type display device and an OCB type display device.
